(19) United States
(12) Patent Application Publication
(10) Pub. No.: US 2023/0203664 A1
(43) Pub. Date: Jun. 29, 2023

(54) WIRING BOARD AND METHOD FOR PRODUCING WIRING BOARD

(71) Applicant: Murata Manufacturing Co., Ltd., Kyoto (JP)

(72) Inventors: Junichi SAITO, Kyoto (JP); Masaaki MIZUSHIRO, Kyoto (JP)

(21) Appl. No.: 18/178,596

(22) Filed: Mar. 6, 2023

Related U.S. Application Data
(63) Continuation of application No. PCT/JP2021/032088, filed on Sep. 1, 2021.

(30) Foreign Application Priority Data
Sep. 8, 2020 (JP) 2020-150470

(51) Int. Cl. C23C 18/16; C23C 18/44

(52) U.S. Cl. CPC C23C 18/1658; C23C 18/1635; C23C 18/44

(57) ABSTRACT

A wiring board includes a substrate having main surfaces and an electrode containing Cu or Ag as a main component on at least one main surface of the substrate, wherein the electrode protrudes from the substrate, a surface of the electrode is covered by a first Ni film containing crystalline Ni as a main component, a surface of the first Ni film is covered by a second Ni film containing amorphous Ni as a main component, and the first Ni film covers a part of a first corner where a side surface of the electrode is in contact with the substrate.

### CROSS REFERENCE TO RELATED APPLICATION

This is a continuation of International Application No. PCT/JP2021/032088 filed on Sep. 1, 2021 which claims priority from Japanese Patent Application No. 2020-150470 filed on Sep. 8, 2020. The contents of these applications are incorporated herein by reference in their entireties.

### BACKGROUND OF THE DISCLOSURE

### Field of the Disclosure

The present disclosure relates to a wiring board and a method of producing the wiring board.

### Description of the Related Art

Electroless Ni plating has been used as a surface treatment of copper wires and copper electrodes of various types of wiring boards. General electroless Ni plating films are amorphous films containing about a few percent of phosphorus (P) derived from a component of a reducing agent.

For example, Patent Literature 1 discloses a semiconductor device including: a copper wire on a substrate; a cap film including a crystalline Ni coating film only on a top surface of the copper wire; and a second barrier film including an amorphous Ni coating film on a top surface of the cap film and side surfaces of the copper wire and the cap film.

### Patent Literature

Patent Literature 1: JP 2016-85998 A

### BRIEF SUMMARY OF THE DISCLOSURE

However, heating the substrate having an electrode structure as disclosed in Patent Literature 1 during reflow soldering or the like may result in defects such as separation of mounted components and poor conductivity.

Assumedly, this is because heating promotes crystallization of the amorphous Ni coating film, generating contraction force in the Ni coating film.

In Patent Literature 1, the amorphous Ni coating film is directly on a side surface of the copper wire on a surface of the substrate. Thus, when heating promotes crystallization of the amorphous Ni coating film and generates contraction force, assumedly, stress will be concentrated at a point where the copper wire, the substrate, and the amorphous Ni coating film are in contact with each other, causing bonding strength reduction and interfacial delamination and resulting in defects such as separation of mounted components and poor conductivity.

The present disclosure solves the above issues and aims to provide a wiring board in which a Ni film is less susceptible to delamination by heating during reflow or the like.

In a first embodiment, the wiring board of the present disclosure includes a substrate having main surfaces and an electrode containing Cu or Ag as a main component on at least one main surface of the substrate, wherein the electrode protrudes from the substrate, a surface of the electrode is covered by a first Ni film containing crystalline Ni as a main component, a surface of the first Ni film is covered by a second Ni film containing amorphous Ni as a main component, and the first Ni film covers a part of a first corner where a side surface of the electrode is in contact with the substrate.

In a second embodiment, the wiring board of the present disclosure includes a substrate having main surfaces; and an electrode containing Cu or Ag as a main component on at least one main surface of the substrate, wherein the electrode protrudes from the substrate, a surface of the electrode is covered by a first Ni film, a surface of the first Ni film is covered by a second Ni film, the first Ni film contains Ni—B, Ni—N, or pure Ni as a main component, the second Ni film contains Ni—P as a main component, and the first Ni film covers a part of a first corner where a side surface of the electrode is in contact with the substrate.

The method of producing the wiring board of the present disclosure includes forming the first Ni film by an electroless nickel plating treatment using a N-containing reducing agent or a B-containing reducing agent as a reducing agent; and forming the second Ni film by an electroless nickel plating treatment using a P-containing reducing agent as a reducing agent.

The present disclosure provides a wiring board in which a Ni film is less susceptible to delamination by heating during reflow or the like.

### BRIEF DESCRIPTION OF THE SEVERAL VIEWS OF THE DRAWINGS

FIG. 1 is a top view schematically showing an example of a wiring board of the present disclosure.

FIG. 2 is a cross-sectional view taken along line A-A in FIG. 1.

### DETAILED DESCRIPTION OF THE DISCLOSURE

Hereinafter, a wiring board of the present disclosure and a method of producing the wiring board are described.

The present disclosure is not limited to the following preferred embodiments, and may be suitably modified without departing from the gist of the present disclosure. Combinations of two or more preferred features described in the following preferred embodiments are also within the scope of the present disclosure.

### Wiring Board According to First Embodiment

The wiring board according to the first embodiment of the present disclosure includes a substrate having main surfaces and an electrode containing Cu or Ag as a main component on at least one main surface of the substrate, wherein the electrode protrudes from the substrate, a surface of the electrode is covered by a first Ni film containing crystalline Ni as a main component, a surface of the first Ni film is covered by a second Ni film containing amorphous Ni as a main component, and the first Ni film covers a part of a first corner where a side surface of the electrode is in contact with the substrate.

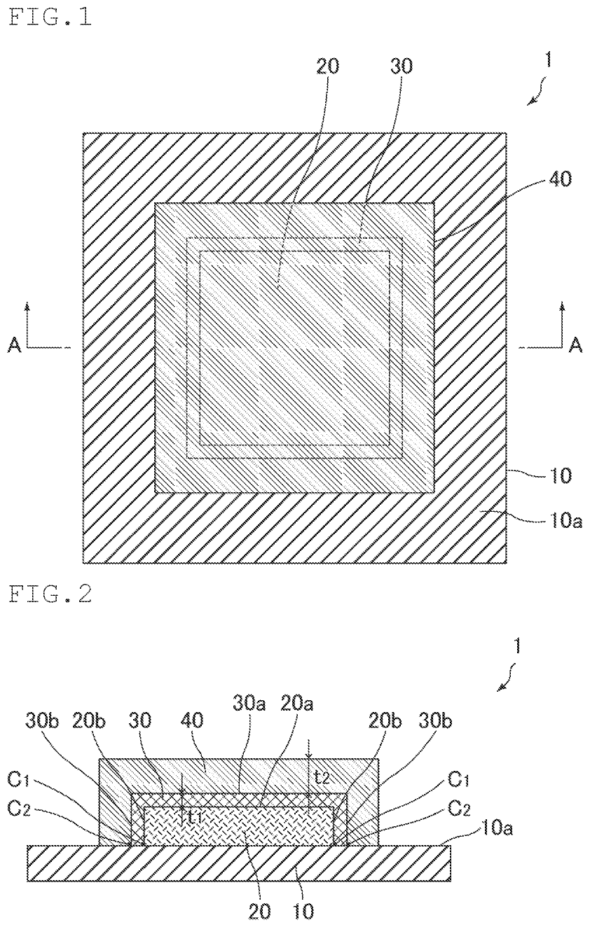

FIG. 1 is a top view schematically showing an example of the wiring board of the present disclosure. FIG. 2 is a cross-sectional view taken along line A-A in FIG. 1.

As shown in FIG. 1 and FIG. 2, a wiring board 1 includes a substrate 10 having main surfaces; an electrode 20 containing Cu or Ag as a main component on one main surface 10a of the substrate 10; a first Ni film 30 covering a surface of the electrode 20; and a second Ni film 40 covering a surface of the first Ni film 30.

As shown in FIG. 2, the electrode 20 protrudes from the substrate 10, and a top surface 20a and side surfaces 20b of the electrode 20 are covered by the first Ni film 30.

The first Ni film 30 covers a first corner (portion indicated by C₁ in FIG. 2) where the side surfaces 20b of the electrode 20 are in contact with the substrate 10. The first corner C₁ where the side surfaces 20b of the electrode 20 are in contact with the substrate 10 are covered by the first Ni film 30 containing crystalline Ni as a main component, so that stress concentration is less likely to occur on the first corner C₁ susceptible to stress concentration.

The first Ni film 30 contains crystalline Ni as a main component. Thus, even when the wiring board 1 is heated during reflow or the like, the first Ni film 30 containing crystalline Ni as a main component does not undergo crystallization and is less subjected to compressive stress. Thus, interfacial delamination is less likely to occur at the interface between the electrode 20 and the first Ni film 30.

When the wiring board 1 is viewed from above, the first corner C₁ surrounds the boundary between the substrate 10 and the electrode 20 along the external shape of the electrode 20.

In the wiring board 1 shown in FIG. 1, the first Ni film 30 covers the entirety of the first corner C₁.

In the wiring board 1, a top surface 30a and side surfaces 30b of the first Ni film 30 are covered by the second Ni film 40 containing amorphous Ni as a main component. The second Ni film 40 covers a second corner (portion indicated by C2 in FIG. 2) where the side surfaces 30b of the first Ni film 30 are in contact with the substrate 10.

The second Ni film containing amorphous Ni as a main component can be formed by electroless nickel plating with medium phosphorus content in which hypophosphorous acid is used as a reducing agent. Such a Ni film is high in strength and excellent in acid resistance. Such a Ni film also facilitates formation of an Au plating film for improving solderability.

When the wiring board is heated during reflow or the like, the second Ni film undergoes crystallization and generates compressive stress. However, the first Ni film and the second Ni film have high interfacial strength because both films contain Ni as a main component, so that interfacial delamination is less likely to occur at the interface between the first Ni film and the second Ni film. In addition, since the electrode is not in direct contact with the second Ni film, interfacial delamination is less likely to occur between the electrode and the first Ni film even when compressive stress is generated in the second Ni film.

Whether the first Ni film contains crystalline Ni as a main component can be determined from X-ray diffraction patterns.

Specifically, X-ray diffraction patterns are measured using FeKα (λ=0.19373 nm) as the X radiation source to check for a peak from (111) of Ni at around 57°. A film showing a peak from (111) of Ni at around 57° is determined as containing crystalline Ni as a main component.

Whether the second Ni film contains amorphous Ni as a main component can be determined from X-ray diffraction patterns.

Specifically, X-ray diffraction patterns are measured using FeKα as the X radiation source to check for a peak from (111) of Ni at around 57°. A film not showing a peak from (111) of Ni at around 57° is determined as containing amorphous Ni as a main component.

Examples of materials of the first Ni film include a material containing Ni—B, Ni—N, or pure Ni as a main component.

Ni—B is a nickel alloy containing boron (B) as an impurity.

The amount of B in Ni—B may be, for example, 0.05 wt % or more and 3 wt % or less.

Ni—N is a nickel alloy containing nitrogen (N) as an impurity.

The amount of N in Ni—N may be, for example, 0.05 wt % or more and 3 wt % or less.

The pure Ni may contain P as an impurity in an amount of 0.05 wt % or more and 4 wt % or less.

The composition of the first Ni film can be measured by inductively coupled plasma (ICP) emission spectrometry.

The first Ni film containing Ni—B as a main component can be formed by electroless nickel plating using a B-containing reducing agent as a reducing agent.

Examples of the B-containing reducing agent include dimethylamine borane, sodium borohydride, and potassium borohydride.

The first Ni film containing Ni—N as a main component can be formed by electroless nickel plating using a N-containing reducing agent as a reducing agent.

Examples of the N-containing reducing agent include hydrazine.

The thickness (the length indicated by a double-headed arrow t₁ in FIG. 2) of the first Ni film is not limited and may be, for example, 0.005 μm or more and 4 μm or less.

Examples of materials of the second Ni film include a material containing Ni—P as a main component.

Ni—P is a nickel alloy containing 5 wt % or more phosphorus (P) as an impurity.

The amount of P in Ni—P may be, for example, 5 wt % or more and 11 wt % or less.

The composition of the second Ni film can be measured by ICP emission spectrometry.

The film thickness (the length indicated by a double-headed arrow t₂ in FIG. 2) of the second Ni film is not limited and may be, for example, 1 μm or more and 4 μm or less.

The second Ni film containing Ni—P as a main component can be formed by electroless nickel plating using a P-containing reducing agent as a reducing agent.

Examples of the P-containing reducing agent include hypophosphites such as sodium hypophosphite and potassium hypophosphite.

The thickness relationship between the first Ni film and the second Ni film is not limited. For example, as shown in FIG. 2, the thickness t₂ of the second Ni film 40 may be greater than the thickness t₁ of the first Ni film 30.

The amount of the first Ni film formation per unit time is small and the stability of a plating bath of the first Ni film is low as compared to the second Ni film, so that the production cost of the first Ni film tends to be high. The surface of the second Ni film is often subjected to Au displacement plating to improve solder wettability. Thus, when there are limitations on the total thickness of the first Ni film and the second Ni film, the thickness of the second Ni film is set to be greater than the thickness of the first Ni film, whereby the stability of Au displacement plating on the surface of the second Ni film can be increased while the production cost is reduced.

The total thickness of the first Ni film and the second Ni film may be, for example, 3 μm or more and 10 μm or less.

The substrate of the wiring board may be a ceramic substrate or a resin substrate.

The wiring board 1 shown in FIG. 1 and FIG. 2 does not include wires and the like inside the substrate 10, but the wiring board of the present disclosure may include wires and the like inside the substrate.

### Second Embodiment of Wiring Board

The wiring board according to the second embodiment of the present disclosure includes a substrate having main surfaces; and an electrode containing Cu or Ag as a main component on at least one main surface of the substrate, wherein the electrode protrudes from the substrate, a surface of the electrode is covered by a first Ni film, a surface of the first Ni film is covered by a second Ni film, the first Ni film contains Ni—B, Ni—N, or pure Ni as a main component, the second Ni film contains Ni—P as a main component, and the first Ni film covers a part of a first corner where a side surface of the electrode is in contact with the substrate.

The wiring board according to the second embodiment of the present disclosure is the same as the wiring board according to the first embodiment of the present disclosure, except that the first Ni film contains Ni—B, Ni—N, or pure Ni as a main component regardless of crystallinity, and the second Ni film contains Ni—P as a main component regardless of crystallinity.

A Ni film containing Ni—B, Ni—N, or pure Ni as a main component has a high crystallinity.

In the wiring board according to the second embodiment of the present disclosure, a part of the first corner where the side surface of the electrode is in contact with the substrate is covered by the first Ni film containing Ni—B, Ni—N, or pure Ni as a main component, so that stress concentration is less likely to occur on the first corner susceptible to stress concentration.

The first Ni film contains Ni—B, Ni—N, or pure Ni as a main component.

Ni—B is a nickel alloy containing boron (B) as an impurity.

The amount of B in Ni—B may be, for example, 0.05 wt % or more and 3 wt % or less.

Ni—N is a nickel alloy containing nitrogen (N) as an impurity.

The amount of N in Ni—N may be, for example, 0.05 wt % or more and 3% wt or less.

The pure Ni may contain P as an impurity in an amount of 0.05 wt % or more and 4 wt % or less.

The type and percentage of each impurity in the first Ni film and the second Ni film can be determined by ICP emission spectrometry.

The term “main component” refers to a component accounting for at least 90 wt % of the total.

The first Ni film containing Ni—B, Ni—N, or pure Ni as a main component has a high crystallinity.

In the wiring board according to the second embodiment of the present disclosure, a part of the first corner where the side surface of the electrode is in contact with the substrate is covered by the first Ni film containing Ni—B, Ni—N, or pure Ni as a main component, so that stress is prevented from being generated by heating during reflow or the like. This suppresses stress concentration at the first corner.

The second Ni film contains Ni—P as a main component.

Ni—P is a nickel alloy containing phosphorus (P) as an impurity.

The amount of P in Ni—P may be, for example, 5 wt % or more and 11 wt % or less.

The wiring board according to the second embodiment of the present disclosure is the same as the wiring board according to the first embodiment of the present disclosure other than what is mentioned above.

### Method of Producing Wiring Board

The method of producing the wiring board of the present disclosure includes forming the first Ni film by an electroless nickel plating treatment using a N-containing reducing agent or a B-containing reducing agent as a reducing agent; and forming the second Ni film by an electroless nickel plating treatment using a P-containing reducing agent as a reducing agent.

The surface of the electrode is electroless nickel plated using a N-containing reducing agent or a B-containing reducing agent as a reducing agent, whereby a Ni film is formed.

Since the Ni film is a crystalline Ni film, it is the first Ni film of the wiring board according to the first embodiment of the present disclosure. Since the Ni film contains a Ni—B or Ni—N as a main component, it is also the first Ni film of the wiring board according to the second embodiment of the present disclosure.

The composition of a plating bath for electroless nickel plating to form the first Ni film may be, for example, a composition in which the concentration of a nickel salt such as nickel acetate or nickel sulfate is 0.025 M or more and 0.1 M or less and the concentration of a B-containing reducing agent or a N-containing reducing agent is 0.02 M or more and 0.1 M or less.

The temperature of the plating bath may be, for example, 50° C. or higher and 90° C. or lower.

The pH of the plating bath may be, for example, 5 or more and 9 or less.

A complexing agent, a stabilizer, a pH adjuster, or the like may be added to the plating bath, if necessary.

The composition of the plating bath for electroless nickel plating to form the second Ni film may be, for example, a composition in which the concentration of a nickel salt such as nickel acetate or nickel sulfate is 0.025 M or more and 0.1 M or less and the concentration of a P-containing reducing agent is 0.025 M or more and 0.3 M or less.

The temperature of the plating bath may be, for example, 80° C. or higher and 90° C. or lower.

The pH of the plating bath may be, for example, 4 or more and 11 or less.

A complexing agent, a stabilizer, a pH adjuster, or the like may be added to the plating bath, if necessary.

### EXAMPLES

Examples that more specifically disclose the wiring board of the present disclosure are described below. The present disclosure is not limited to these examples.

### Example 1

### Formation of Electrode on Substrate

First, a seed layer was formed by sputtering on a predetermined region of an alumina substrate, and a copper electrode was then formed by electroplating on a surface of the seed layer. The copper electrode was 1 μm thick.

### Formation of First Ni Film

Subsequently, the workpiece was immersed in a plating bath having a composition shown below for 30 seconds to form a first Ni film by electroless nickel plating on surfaces (a top surface and side surfaces) of the copper electrode. The first Ni film formed was 0.005 μm thick as measured by a fluorescent X-ray film thickness meter.

### Composition of Plating Bath

0.02 M nickel sulfate
0.02 M dimethylamine borane
0.1 M glycine

### Temperature: 50° C.

pH: 6.5

### Formation of Second Ni Film

Subsequently, the workpiece was immersed in a plating bath having a composition shown below for 30 minutes to form a second Ni film by electroless nickel plating on surfaces (a top surface and side surfaces) of the first Ni film. The second Ni film formed was 3 μm thick as measured by a fluorescent X-ray film thickness meter.

### Composition of Plating Bath

0.1 M nickel sulfate
0.25 M sodium hypophosphite
0.3 M glycine

### Temperature: 80° C.

pH: 4.5

### Formation of Au Plating Film

Lastly, a surface of the second Ni film was subjected to Au displacement plating. The Au plating film formed was 0.1 μm thick.

A wiring board according to Example 1 was obtained by the above procedure.

### Confirmation of Crystallinity of Ni Film

The thus-obtained wiring board according to Example 1 was cut in the thickness direction to expose the first Ni film and the second Ni film. Then, cross-sectional surfaces were analyzed by X-ray diffraction spectroscopy (radiation source: FeKα).

An X-ray diffraction pattern of the first Ni film showed a peak from Ni (111) at around 57°. Thus, the first Ni film was confirmed as containing crystalline Ni as a main component.

In contrast, an X-ray diffraction pattern of the second Ni film did not show a peak from Ni (111) at around 57°. Thus, the second Ni film was confirmed as containing amorphous Ni as a main component.

The results confirmed that the wiring board according to Example 1 was the wiring board according to the first embodiment board of the present disclosure.

### Measurement of Compositions of First Ni Film and Second Ni Film

The Au film was removed by polishing to expose the second Ni film. Then, the second Ni film was dissolved in aqua regia to obtain a sample. The sample was analyzed by ICP emission spectrometry, whereby the composition of the second Ni film was measured. The second Ni film was made of Ni—P containing 8 wt % phosphorus (P) and 92 wt % nickel (Ni).

The procedure for the second Ni film was repeated. The Au film and the second Ni film were removed by polishing to expose the first Ni film, and the first Ni film was dissolved in aqua regia to obtain a sample. The sample was analyzed by ICP emission spectrometry, whereby the composition of the first Ni film was measured. The first Ni film was a Ni—B film containing 1 wt % boron (B) and 99 wt % nickel (Ni).

The results confirmed that the wiring board according to Example 1 was the wiring board according to the second embodiment of the present disclosure.

Delamination Test after Heating

The wiring board according to Example 1 was heated at 300° C. for three hours. Subsequently, a scratch test was performed using a scratch tester to check for the occurrence of delamination of the Ni films. The scratch test was performed using a diamond indenter (tip radius: 0.8 mm) at an indenter moving speed of 10 mm/min with a scratch distance of 5 mm and a test load of 50 N. Whether the Ni films were delaminated after the delamination test was checked. Table 1 shows the results.

### Examples 2 to 4

Wiring boards according to Example 2 to 4 were produced by the same procedure as in Example 1 without changing the composition of the plating bath, except that the immersion time was changed and the thickness of the first Ni film and the thickness of the second Ni film were changed as shown in Table 1. Then, delamination tests were performed after heating. Table 1 shows the results.

### Comparative Example 1

A wiring board according to Comparative Example 1 was produced by the same procedure as in Example 1, except that the second Ni film was directly formed on the surface of the electrode without forming the first Ni film. Then, delamination tests were performed after heating. Table 1 shows the results.

TABLE 1

| | | First Ni film | | Second Ni film | | Au plating film | |
|---|---|---|---|---|---|---|---|
| | | | Thickness | | Thickness | Thickness | Delamination |
| | Electrode | Crystallinity | [μm] | Crystallinity | [μm] | [μm] | test after heating |
| Example 1 | Cu | Crystalline | 0.005 | Amorphous | 3 | 0.1 | Not delaminaed |
| Example 2 | Cu | Crystalline | 0.1 | Amorphous | 3 | 0.1 | Not delaminated |
| Example 3 | Cu | Crystalline | 1 | Amorphous | 2 | 0.1 | Not delaminated |
| Example 4 | Cu | Crystalline | 2 | Amorphous | 1 | 0.1 | Not delaminated |
| Comparative | Cu | — | — | Amorphous | 3 | 0.1 | Delaminated |
| Example 1 | | | | | | | |

The results in Table 1 confirmed that the wiring board of the present disclosure was excellent in adhesion after heating and that the Ni films were less susceptible to delamination by heating during reflow or the like.
1 wiring board
10 substrate
10a one main surface of substrate
20 electrode
20a top surface of electrode
20b side surface of electrode
30 first Ni film
30a top surface of first Ni film
30b side surface of first Ni film
40 second Ni film
C₁ first corner where side surface of electrode is in contact with substrate
C₂ Second corner where side surface of first Ni film is in contact with substrate
t₁ thickness of first Ni film
t₂ thickness of second Ni film

1. A wiring board comprising:
a substrate having main surfaces; and
an electrode containing Cu or Ag as a main component on at least one of the main surfaces of the substrate,
wherein the electrode protrudes from the substrate,
a surface of the electrode is covered by a first Ni film containing crystalline Ni as a main component,
a surface of the first Ni film is covered by a second Ni film containing amorphous Ni as a main component, and
the first Ni film covers a part of a first corner where a side surface of the electrode is in contact with the substrate.

2. The wiring board according to claim 1,
wherein the first Ni film contains Ni—B, Ni—N, or pure Ni as a main component, and
the second Ni film contains Ni—P as a main component.

3. A wiring board comprising:
a substrate having main surfaces; and
an electrode containing Cu or Ag as a main component on at least one of the main surfaces of the substrate,
wherein the electrode protrudes from the substrate,
a surface of the electrode is covered by a first Ni film,
a surface of the first Ni film is covered by a second Ni film,
the first Ni film contains Ni—B, Ni—N, or pure Ni as a main component,
the second Ni film contains Ni—P as a main component, and
the first Ni film covers a part of a first corner where a side surface of the electrode is in contact with the substrate.

4. The wiring board according to claim 1,
wherein the second Ni film covers a part of a second corner where a side surface of the first Ni film is in contact with the substrate.

5. The wiring board according to claim 1,
wherein the second Ni film is thicker than the first Ni film.

6. The wiring board according to claim 1,
wherein a total thickness of the first Ni film and the second Ni film is 3 μm or more and 10 μm or less.

7. A method of producing the wiring board as defined in claim 1, the method comprising:
forming the first Ni film by an electroless nickel plating treatment using a N-containing reducing agent or a B-containing reducing agent as a reducing agent; and
forming the second Ni film by an electroless nickel plating treatment using a P-containing reducing agent as a reducing agent.

8. The wiring board according to claim 2,
wherein the second Ni film covers a part of a second corner where a side surface of the first Ni film is in contact with the substrate.

9. The wiring board according to claim 3,
wherein the second Ni film covers a part of a second corner where a side surface of the first Ni film is in contact with the substrate.

10. The wiring board according to claim 2,
wherein the second Ni film is thicker than the first Ni film.

11. The wiring board according to claim 3,
wherein the second Ni film is thicker than the first Ni film.

12. The wiring board according to claim 4,
wherein the second Ni film is thicker than the first Ni film.

13. The wiring board according to claim 2,
wherein a total thickness of the first Ni film and the second Ni film is 3 μm or more and 10 μm or less.

14. The wiring board according to claim 3,
wherein a total thickness of the first Ni film and the second Ni film is 3 μm or more and 10 μm or less.

15. The wiring board according to claim 4,
wherein a total thickness of the first Ni film and the second Ni film is 3 μm or more and 10 μm or less.

16. The wiring board according to claim 5,
wherein a total thickness of the first Ni film and the second Ni film is 3 μm or more and 10 μm or less.

17. A method of producing the wiring board as defined in claim 2, the method comprising:
forming the first Ni film by an electroless nickel plating treatment using a N-containing reducing agent or a B-containing reducing agent as a reducing agent; and
forming the second Ni film by an electroless nickel plating treatment using a P-containing reducing agent as a reducing agent.

18. A method of producing the wiring board as defined in claim 3, the method comprising:
forming the first Ni film by an electroless nickel plating treatment using a N-containing reducing agent or a B-containing reducing agent as a reducing agent; and
forming the second Ni film by an electroless nickel plating treatment using a P-containing reducing agent as a reducing agent.

19. A method of producing the wiring board as defined in claim 4, the method comprising:
forming the first Ni film by an electroless nickel plating treatment using a N-containing reducing agent or a B-containing reducing agent as a reducing agent; and
forming the second Ni film by an electroless nickel plating treatment using a P-containing reducing agent as a reducing agent.

20. A method of producing the wiring board as defined in claim 5, the method comprising:
forming the first Ni film by an electroless nickel plating treatment using a N-containing reducing agent or a B-containing reducing agent as a reducing agent; and
forming the second Ni film by an electroless nickel plating treatment using a P-containing reducing agent as a reducing agent.
